(19) United States
(12) Patent Application Publication
(10) Pub. No.: US 2019/0355836 A1
(43) Pub. Date: Nov. 21, 2019

(54) MANUFACTURING METHOD FOR AMORPHOUS SILICON TFT SUBSTRATE

(71) Applicant: Wuhan China Star Optoelectronics Technology Co., Ltd., Wuhan (CN)

(72) Inventor: Guanghui Liu, Wuhan (CN)

(73) Assignee: Wuhan China Star Optoelectronics Technology Co., Ltd., Wuhan (CN)

(21) Appl. No.: 16/313,045

(22) PCT Filed: Sep. 27, 2018
(86) PCT No.: PCT/CN2018/108074

§ 371 Date: Dec. 23, 2018

(30) Foreign Application Priority Data
May 21, 2018 (CN) 201810488941.2

(51) Int. Cl. H01L 29/66; H01L 21/308; H01L 21/3213; H01L 21/02; H01L 21/768; H01L 21/285; H01L 27/12

(52) U.S. Cl. CPC H01L 29/66757; H01L 21/308; H01L 21/32139; H01L 21/02068; H01L 27/1288; H01L 21/76895; H01L 21/28556; H01L 21/2855; H01L 21/02576; H01L 21/02271

(57) ABSTRACT

A manufacturing method for amorphous silicon TFT substrate is provided. A first photoresist layer having three thicknesses is formed through a first exposure process. Through three etching processes and two ashing treatments, patterning four layers of amorphous silicon layer, N-type doped amorphous silicon layer, first transparent conductive layer, and the source drain metal layer is completed by the first photoresist layer. Patterning of passivation layer is then performed via a second exposure process. Finally, a second photoresist layer having a photoresist pattern with two thicknesses is formed through a third exposure process. Patterning the two layers of the second transparent conductive layer and the gate metal layer by the second photoresist layer by two etching processes and one ashing process. The present invention further saves a mask process compared with the existing 4mask process, realizing a 3mask fabrication process of the amorphous silicon TFT substrate.

### FIELD OF THE INVENTION

The present invention relates to a display technology field, and more particularly to a manufacturing method for amorphous silicon TFT substrate.

### BACKGROUND OF THE INVENTION

In the field of display technology, a flat panel display devices such as a liquid crystal display (LCD) and an active matrix organic light-emitting diode (AMOLED) display have many advantages of thin body, high image quality, power saving, no radiation so that the above displays are widely applied in the field such as mobile phone, personal digital assistant (PDA), digital camera, computer screen or notebook screen.

The Thin-Film Transistor (TFT) Array substrate is a main component of current LCD device and AMOLED device. It is directly related to the development direction of high-performance flat panel display device. It is used to provide driving circuits to the displays. Multiple gate scanning lines and multiple data lines are usually provided. The multiple gate scanning lines and the multiple data lines defines multiple pixel units, each pixel unit is provided with a thin-film transistor and a pixel electrode, and a gate electrode of the thin-film transistor and corresponding gate scanning lines are connected. When the voltage on the gate scanning line reaches the turn-on voltage, source electrode and drain electrode of the thin-film transistor are turned on, thereby inputting the data voltage on the data line to the pixel electrode so as to control the display of corresponding pixel region.

According to the difference in semiconductor materials in TFTs, the TFTs are mainly classified into an amorphous silicon (A-Si) TFT and a Low Temperature Poly-Silicon (LTPS) TFTs. Comparing with LTPS TFT technology, the amorphous silicon TFT has low resolution and high power consumption, but its fabrication cycle is short, the cost is low, and it is easy to carry out a large-area process. Therefore, it is a popular product in the market and is widely applied in the current semiconductor industry.

In the mass production line of semiconductor production, the exposure (Photo) equipment is the most core and most expensive equipment. Therefore, the production capacity of the mass production line is determined by the exposure equipment, so in the development of the semiconductor industry, saving the use of the mask, increasing the production capacity and reducing the cost become the main demand for technological development. In the fabrication process of amorphous silicon TFT, the 6mask process is usually used. Recently, through optimization design, it gradually transitions to 5mask or even 4mask process, but this still cannot meet the increasing capacity requirements of TFT array substrates.

### SUMMARY OF THE INVENTION

An object of the present invention is to provide a manufacturing method for amorphous silicon TFT substrate, which can produce an amorphous silicon TFT substrate by a 3mask process, thereby improving the overall productivity of the factory and reducing the cost.

In order to realize the above purpose, the present invention provides a manufacturing method for amorphous silicon TFT substrate, including following steps:

step S1, providing a base substrate, and sequentially depositing an amorphous silicon layer, an N-type doped amorphous silicon layer, a first transparent conductive layer, and a source drain metal layer on the base substrate;

step S2, coating a photoresist material on the source drain metal layer and performing a first mask process to form a first photoresist layer, wherein the first photoresist layer has a first photoresist pattern, a second photoresist pattern, and a third photoresist pattern which are sequentially increased in thickness;

Step S3, performing a first etching process by using the first photoresist layer as a shielding layer to remove the amorphous silicon layer, the N-type doped amorphous silicon layer, and the first transparent conductive layer and the source drain metal layer that are not covered by the first photoresist layer, wherein an amorphous silicon active layer is obtained from the amorphous silicon layer corresponding to an underside of the first photoresist pattern and the second photoresist pattern, and a pixel electrode is obtained from the first transparent conductive layer corresponding to an underside of the third photoresist pattern;

Step S4, performing a first ashing treatment on the first photoresist layer, thinning the second photoresist pattern and the third photoresist pattern, and removing the first photoresist pattern;

Step S5, performing a second etching process using the first photoresist layer as a shielding layer to remove the N-type doped amorphous silicon layer, the first transparent conductive layer, and the source drain metal layer that are not covered by the first photoresist layer, wherein a source electrode and a drain electrode are obtained from the source drain metal layer located above two ends of the amorphous silicon active layer and corresponding to an underside of the second photoresist pattern, and a source-drain contact region is obtained from the N-type doped amorphous silicon layer corresponding to an underside of the source electrode and the drain electrode;

Step S6, performing a second ashing treatment to the first photoresist layer, thinning the third photoresist pattern and removing the second photoresist pattern;

Step S7, performing a third etching process by using the first photoresist layer as a shielding layer, and removing the source drain metal layer corresponding to an upside of the pixel electrode to expose the pixel electrode, and peeling off a remaining portion of the first photoresist layer;

Step S8, depositing a passivation layer that covers the amorphous silicon active layer, the source electrode, the drain electrode, and the pixel electrode on the base substrate, through a second mask process, forming a first via and a second via respectively corresponding to the drain electrode and the pixel electrode on the passivation layer;

Step S9, sequentially depositing a second transparent conductive layer and a gate metal layer on the passivation layer, coating a photoresist material on the source drain metal layer and performing a third mask process to form a second photoresist layer, wherein the second photoresist layer has a fourth photoresist pattern and a fifth photoresist pattern which are sequentially increased in thickness;

Step S10, performing a first etching process using the second photoresist layer as a shielding layer to remove the second transparent conductive layer and the gate metal layer which are not covered by the second photoresist layer, wherein corresponding to an underside of the fourth photoresist pattern, a gate electrode and a metal common electrode line separated from the gate electrode which are corresponding to an upside of the amorphous silicon active layer are obtained; corresponding to an underside of the fifth photoresist pattern, a conductive connection block and a transparent common electrode line separated from the conductive connection block are obtained from the second transparent conductive layer; wherein the conductive connection block is contacted with the drain electrode and the pixel electrode respectively through the first via and the second via in order to electrically conduct the drain electrode and the pixel electrode;

Step S11, performing a first ashing treatment to the second photoresist layer, thinning the fifth photoresist pattern and removing the fourth photoresist pattern; and

Step S12, performing a second etching process using the second photoresist layer as a shielding layer to remove the gate metal layer corresponding to an upside of the conductive connection block and the transparent common electrode line, and peeling off a remaining portion of the second photoresist layer.

Wherein in the step S2, the first mask process is performed by a Gray Tone Mask.

Wherein in the step S9, the third mask process is performed by a Gray Tone Mask or a Half Tone Mask.

Wherein in the step S2, the coated photoresist material is a positive photoresist material, and in the first mask process, the photoresist material is divided into four portions exposed under four exposure degrees that is gradually reduced from a full exposure degree to a non-exposure degree, the four portions that the exposure degrees are gradually decreased are respectively removed after developing in order to form the first photoresist pattern, the second photoresist pattern and the third photoresist pattern.

Wherein in the step S9, the coated photoresist material is a positive photoresist material, and in the third mask process, the photoresist material is divided into three portions exposed under three exposure degrees that are from a full exposure degree to a non-exposure degree. The three portions exposed under the three exposure degrees are respectively removed after being developed in order to formed a fourth photoresist pattern and a fifth photoresist pattern.

Wherein a material of each of the first transparent conductive layer and the second transparent conductive layer is indium tin oxide (ITO).

Wherein in the step S1, the amorphous silicon layer, the N-type doped amorphous silicon layer, and the first transparent conductive layer are formed by a chemical vapor deposition (CVD), the source drain metal layer is formed by a sputter method.

Wherein in the step S8, the passivation layer is formed by a chemical vapor deposition.

Wherein in the step S9, the second transparent conductive layer is deposited by a chemical vapor deposition, and the gate metal layer is formed by a sputter method.

Wherein in the step S1, the N-type doped amorphous silicon layer 30 is formed by adding phosphine during the deposition process.

Advantageous effects of the present invention, in the manufacturing method for the amorphous silicon TFT substrate of the present invention, first, a first photoresist layer having three thicknesses is formed through a first exposure process, and through three etching processes and two ashing treatments, patterning four layers of the amorphous silicon layer, the N-type doped amorphous silicon layer, the first transparent conductive layer, and the source drain metal layer is completed by the first photoresist layer. Patterning of passivation layer is then performed via a second exposure process. Finally, a second photoresist layer having a photoresist pattern having two thicknesses is formed through a third exposure process. Patterning of the two layers of the second transparent conductive layer and the gate metal layer by the second photoresist layer by two etching processes and one ashing process. By optimizing the process, the present invention further saves a mask process compared with the existing 4mask process, realizing a 3mask fabrication process of the amorphous silicon TFT substrate, thereby improving the overall capacity of the factory and reducing the costs.

### BRIEF DESCRIPTION OF THE DRAWINGS

In order to further understand the features and technical contents of the present invention, please refer to the following detailed description and drawings regarding the present invention. The drawings are provided for purposes of illustration and description only and are not intended to be limiting.

In the figures,

FIG. 1 is a schematic flow chart of a manufacturing method for amorphous silicon TFT substrate of the present invention.

FIG. 2 is a schematic diagram of a step S1 of the manufacturing method for amorphous silicon TFT substrate of the present invention.

FIG. 3 is a schematic diagram of a step S2 of the manufacturing method for amorphous silicon TFT substrate of the present invention.

FIG. 4 is a schematic diagram of a step S3 of the manufacturing method for amorphous silicon TFT substrate of the present invention.

FIG. 5 is a schematic diagram of a step S4 of the manufacturing method for amorphous silicon TFT substrate of the present invention.

FIG. 6 is a schematic diagram of a step S5 of the manufacturing method for amorphous silicon TFT substrate of the present invention.

FIG. 7 is a schematic diagram of a step S6 of the manufacturing method for amorphous silicon TFT substrate of the present invention.

FIG. 8-FIG. 9 are schematic diagrams of a step S7 of the manufacturing method for amorphous silicon TFT substrate of the present invention.

FIG. 10 is a schematic diagram of a step S8 of the manufacturing method for amorphous silicon TFT substrate of the present invention.

FIG. 11 is a schematic view showing a step S9 of the method for fabricating an amorphous silicon TFT substrate of the present invention;

FIG. 12 is a schematic diagram of a step S10 of the manufacturing method for amorphous silicon TFT substrate of the present invention.

FIG. 13 is a schematic diagram of a step S11 of the manufacturing method for amorphous silicon TFT substrate of the present invention.

FIG. 14-FIG. 15 are schematic diagrams of a step S12 of the manufacturing method for amorphous silicon TFT substrate of the present invention.

### DETAILED DESCRIPTION OF PREFERRED EMBODIMENTS

To further explain the technical means and effects of the present invention, hereinafter, a preferred embodiment of the present invention and its drawings are combined to perform a detailed description.

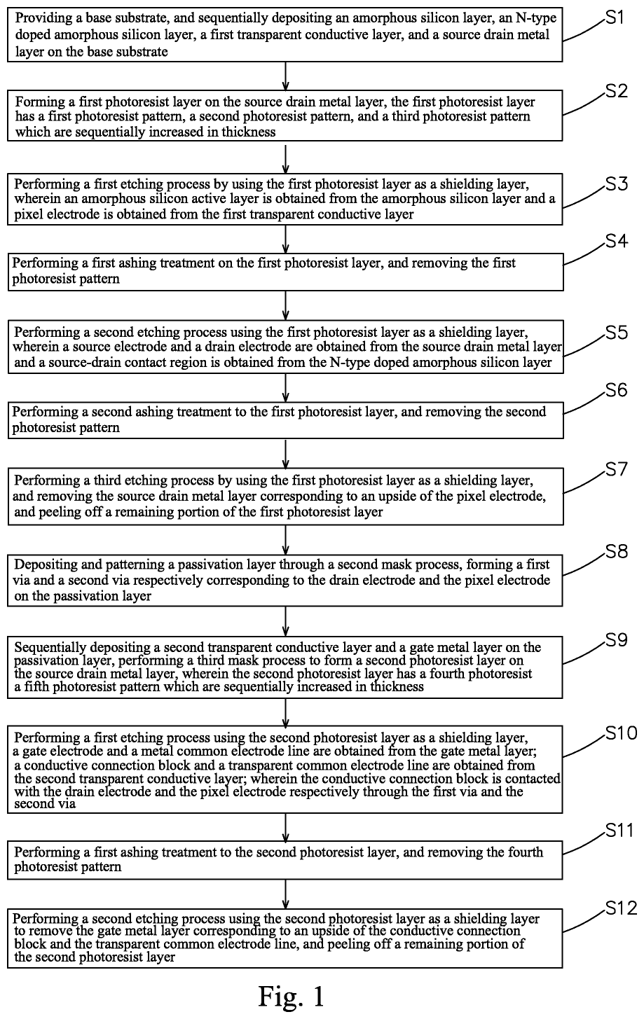

Referring to FIG. 1, the present invention provides a manufacturing method for amorphous silicon TFT substrate, including the following steps:

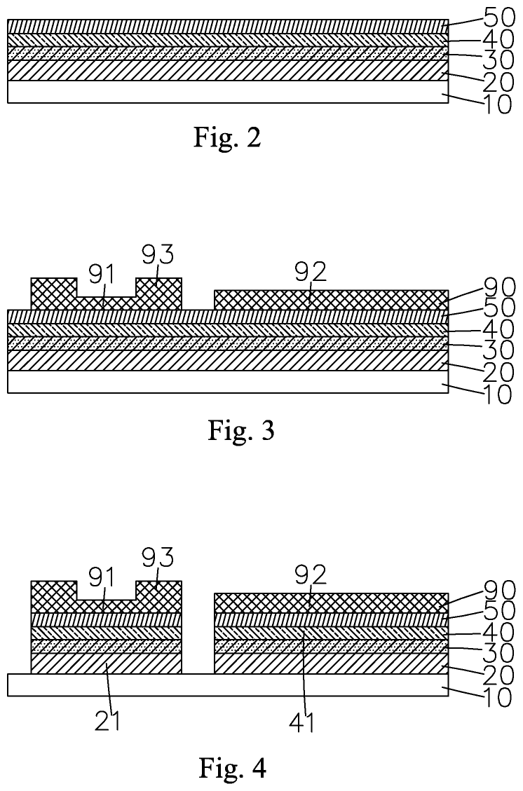

Step S1, as shown in FIG. 2, providing a base substrate 10, and sequentially depositing an amorphous silicon layer 20, an N-type doped amorphous silicon layer 30, a first transparent conductive layer 40, and a source drain metal layer 50 on the base substrate 10.

Specifically, the material of the first transparent conductive layer 40 is indium tin oxide (ITO).

Specifically, in the step S1, the amorphous silicon layer 20, the N-type doped amorphous silicon layer 30, and the first transparent conductive layer 40 are formed by the chemical vapor deposition (CVD), the source drain metal layer 50 is formed by the sputter method. In addition, the amorphous silicon layer 20, the N-type doped amorphous silicon layer 30, the first transparent conductive layer 40, and the source drain metal layer 50 may be formed by other fabrication methods.

Specifically, in the step S1, the N-type doped amorphous silicon layer 30 is formed by adding phosphine during the deposition process.

Step S2, as shown in FIG. 3, coating a photoresist material on the source drain metal layer 50 and performing a first mask process to form a first photoresist layer 90, wherein the first photoresist layer 90 has a first photoresist pattern 91, a second photoresist pattern 92, and a third photoresist pattern 93 which are sequentially increased in thickness.

Specifically, in the step S2, the first mask process is performed by a Gray Tone Mask (GTM).

Furthermore, in the step S2, the coated photoresist material is a positive photoresist material, and in the first mask process, the photoresist material is divided into four portions exposed under four exposure degrees that is gradually reduced from a full exposure degree to a non-exposure degree. The four portions that the exposure degrees are gradually decreased are respectively removed after developing in order to form the first photoresist pattern 91, the second photoresist pattern 92, and the third photoresist pattern 93.

Step S3, as shown in FIG. 4, performing a first etching process by using the first photoresist layer 90 as a shielding layer to remove the amorphous silicon layer 20, the N-type doped amorphous silicon layer 30, and the first transparent conductive layer 40 and the source drain metal layer 50 that are not covered by the first photoresist layer 90. Wherein, an amorphous silicon active layer 21 is obtained from the amorphous silicon layer 20 corresponding to an underside of the first photoresist pattern 91 and the second photoresist pattern 92, and a pixel electrode 41 is obtained from the first transparent conductive layer 40 corresponding to an underside of the third photoresist pattern 93.

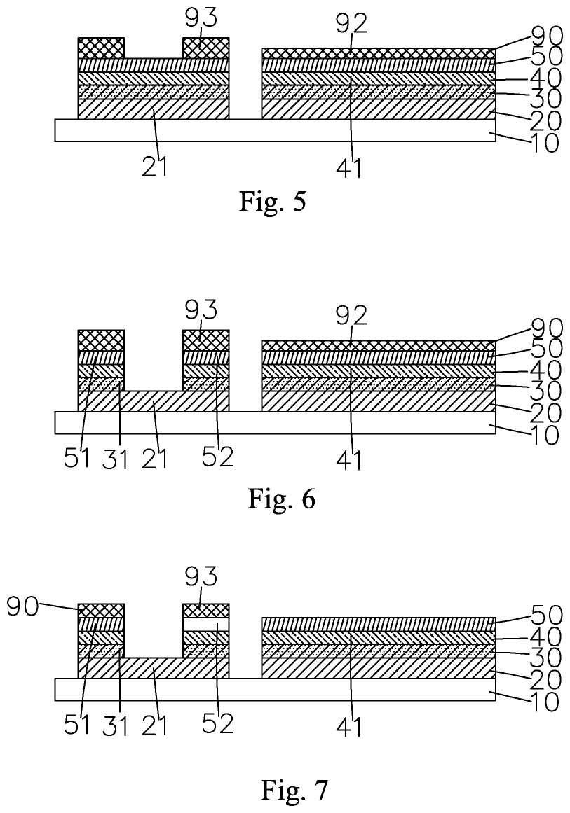

Step S4, as shown in FIG. 5, performing a first ashing treatment on the first photoresist layer 90, thinning the second photoresist pattern 92 and the third photoresist pattern 93, and removing the first photoresist pattern 91.

Step S5, as shown in FIG. 6, performing a second etching process using the first photoresist layer 90 as a shielding layer to remove the N-type doped amorphous silicon layer 30, the first transparent conductive layer 40, and the source drain metal layer 50 that are not covered by the first photoresist layer 90. A source electrode 51 and a drain electrode 52 are obtained from the source drain metal layer 50 located above two ends of the amorphous silicon active layer 21 and corresponding to an underside of the second photoresist pattern 92. A source-drain contact region 31 is obtained from the N-type doped amorphous silicon layer 30 corresponding to an underside of the source electrode 51 and the drain electrode 52.

Step S6, as shown in FIG. 7, performing a second ashing treatment to the first photoresist layer 90, thinning the third photoresist pattern 93 and removing the second photoresist pattern 92.

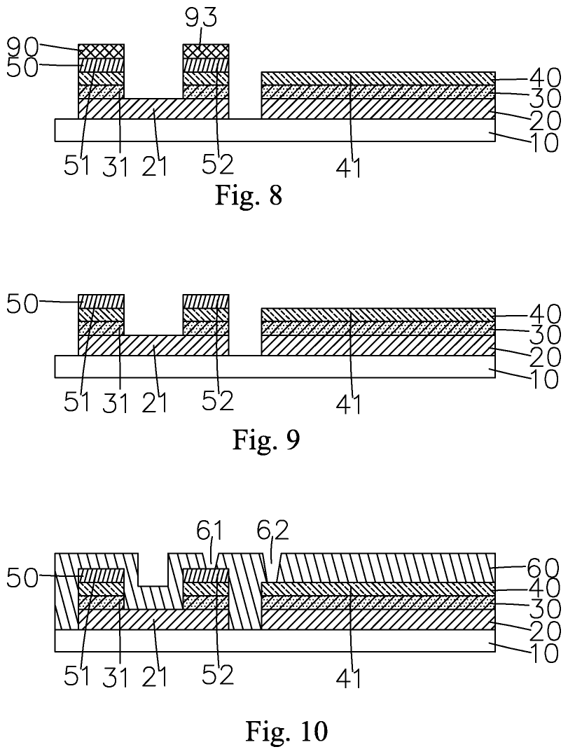

Step S7, as shown in FIG. 8-9, performing a third etching process by using the first photoresist layer 90 as a shielding layer, and removing the source drain metal layer 50 corresponding to an upside of the pixel electrode 41 to expose the pixel electrode 41; peeling off a remaining portion of the first photoresist layer 90.

Step S8, as shown in FIG. 10, depositing a passivation layer 60 that covers the amorphous silicon active layer 21, the source electrode 51, the drain electrode 52, and the pixel electrode 41 on the base substrate 10. Through a second mask process, forming a first via 61 and a second via 62 respectively corresponding to the drain electrode 52 and the pixel electrode 41 on the passivation layer 60.

Specifically, in the step S8, the passivation layer 60 is formed by the chemical vapor deposition.

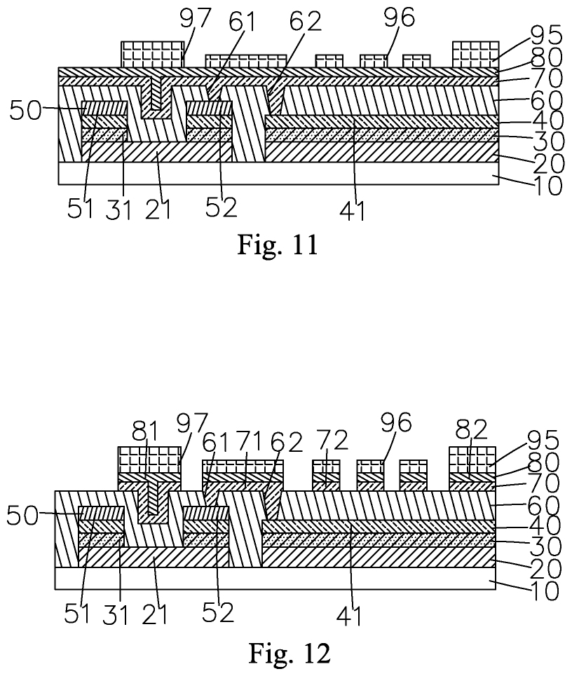

Step S9, as shown in FIG. 11, sequentially depositing a second transparent conductive layer 70 and a gate metal layer 80 on the passivation layer 60; coating a photoresist material on the source drain metal layer 50 and performing a third mask process to form a second photoresist layer 95, wherein the second photoresist layer 95 has a fourth photoresist pattern 96 and a fifth photoresist pattern 97 which are sequentially increased in thickness.

Specifically, in the step S9, the third mask process is performed by a Gray Tone Mask or a Half Tone Mask (HTM).

Furthermore, in the step S9, the coated photoresist material is a positive photoresist material, and in the third mask process, the photoresist material is divided into three portions exposed under three exposure degrees that are from a full exposure degree to a non-exposure degree. The three portions exposed under the three exposure degrees are respectively removed after being developed in order to formed a fourth photoresist pattern 96 and a fifth photoresist pattern 97.

Specifically, the material of the second transparent conductive layer 70 is indium tin oxide.

In the step S9, the second transparent conductive layer 70 is deposited by the chemical vapor deposition, and the gate metal layer 80 is formed by a sputter method. In addition, the second transparent conductive layer 70 and the gate metal layer 80 may be formed by other fabrication methods.

Step S10, as shown in FIG. 12, performing a first etching process using the second photoresist layer 95 as a shielding layer to remove the second transparent conductive layer 70 and the gate metal layer 80 which are not covered by the second photoresist layer 95. Corresponding to an underside of the fourth photoresist pattern 96, a gate electrode 81 and a metal common electrode line 82 separated from the gate electrode 81 which are corresponding to an upside of the amorphous silicon active layer 21 are obtained. Corresponding to an underside of the fifth photoresist pattern 97, a conductive connection block 71 and a transparent common electrode line 72 separated from the conductive connection block 71 are obtained from the second transparent conductive layer 70. Wherein the conductive connection block 71 is contacted with the drain electrode 52 and the pixel electrode 41 respectively through the first via 61 and the second via 62 in order to electrically conduct the drain electrode 52 and the pixel electrode 41.

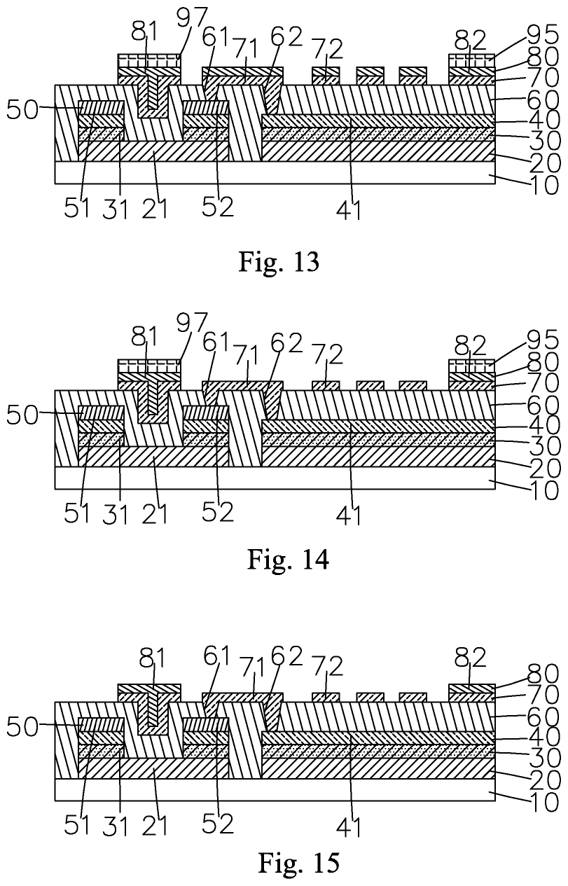

Step S11, as shown in FIG. 13, performing a first ashing treatment to the second photoresist layer 95, thinning the fifth photoresist pattern 97 and removing the fourth photoresist pattern 96;

Step S12, as shown in FIG. 14-15, performing a second etching process using the second photoresist layer 95 as a shielding layer to remove the gate metal layer 80 corresponding to an upside of the conductive connection block 71 and the transparent common electrode line 72, and peeling off a remaining portion of the second photoresist layer 95.

In the manufacturing method for the amorphous silicon TFT substrate of the present invention, first, a first photoresist layer 90 having three thicknesses is formed through a first exposure process, and through three etching processes and two ashing treatments, patterning four layers of the amorphous silicon layer 20, the N-type doped amorphous silicon layer 30, the first transparent conductive layer 40, and the source drain metal layer 50 is completed by the first photoresist layer 90. Patterning of passivation layer 60 is then performed via a second exposure process. Finally, a second photoresist layer 95 having a photoresist pattern having two thicknesses is formed through a third exposure process. Patterning of the two layers of the second transparent conductive layer 70 and the gate metal layer 80 by the second photoresist layer 95 by two etching processes and one ashing process. By optimizing the process, the present invention further saves a mask process compared with the existing 4mask process, realizing a 3mask fabrication process of the amorphous silicon TFT substrate, and completes the fabrication of the amorphous silicon TFT substrate through the three mask processes, thereby improving the overall capacity of the factory and reducing the costs.

In summary, in the manufacturing method for the amorphous silicon TFT substrate of the present invention, first, a first photoresist layer having three thicknesses is formed through a first exposure process, and through three etching processes and two ashing treatments, patterning four layers of the amorphous silicon layer, the N-type doped amorphous silicon layer, the first transparent conductive layer, and the source drain metal layer is completed by the first photoresist layer. Patterning of passivation layer is then performed via a second exposure process. Finally, a second photoresist layer having a photoresist pattern having two thicknesses is formed through a third exposure process. Patterning of the two layers of the second transparent conductive layer and the gate metal layer by the second photoresist layer by two etching processes and one ashing process. By optimizing the process, the present invention further saves a mask process compared with the existing 4mask process, realizing a 3mask fabrication process of the amorphous silicon TFT substrate, thereby improving the overall capacity of the factory and reducing the costs.

As described above, for those of ordinary skill in the art, various other corresponding changes and modifications can be made according to the technical solutions and technical ideas of the present invention. All such changes and modifications are intended to be included within the scope of the appended claims.

What is claimed is:

1. A manufacturing method for amorphous silicon TFT substrate, comprising steps of:
step S1, providing a base substrate, and sequentially depositing an amorphous silicon layer, an N-type doped amorphous silicon layer, a first transparent conductive layer, and a source drain metal layer on the base substrate;
step S2, coating a photoresist material on the source drain metal layer and performing a first mask process to form a first photoresist layer, wherein the first photoresist layer has a first photoresist pattern, a second photoresist pattern, and a third photoresist pattern which are sequentially increased in thickness;
Step S3, performing a first etching process by using the first photoresist layer as a shielding layer to remove the amorphous silicon layer, the N-type doped amorphous silicon layer, and the first transparent conductive layer and the source drain metal layer that are not covered by the first photoresist layer, wherein an amorphous silicon active layer is obtained from the amorphous silicon layer corresponding to an underside of the first photoresist pattern and the second photoresist pattern, and a pixel electrode is obtained from the first transparent conductive layer corresponding to an underside of the third photoresist pattern;
Step S4, performing a first ashing treatment on the first photoresist layer, thinning the second photoresist pattern and the third photoresist pattern, and removing the first photoresist pattern;
Step S5, performing a second etching process using the first photoresist layer as a shielding layer to remove the N-type doped amorphous silicon layer, the first transparent conductive layer, and the source drain metal layer that are not covered by the first photoresist layer, wherein a source electrode and a drain electrode are obtained from the source drain metal layer located above two ends of the amorphous silicon active layer and corresponding to an underside of the second photoresist pattern, and a source-drain contact region is obtained from the N-type doped amorphous silicon layer corresponding to an underside of the source electrode and the drain electrode;
Step S6, performing a second ashing treatment to the first photoresist layer, thinning the third photoresist pattern and removing the second photoresist pattern;
Step S7, performing a third etching process by using the first photoresist layer as a shielding layer, and removing the source drain metal layer corresponding to an upside of the pixel electrode to expose the pixel electrode, and peeling off a remaining portion of the first photoresist layer;
Step S8, depositing a passivation layer that covers the amorphous silicon active layer, the source electrode, the drain electrode, and the pixel electrode on the base substrate, through a second mask process, forming a first via and a second via respectively corresponding to the drain electrode and the pixel electrode on the passivation layer;
Step S9, sequentially depositing a second transparent conductive layer and a gate metal layer on the passivation layer, coating a photoresist material on the source drain metal layer and performing a third mask process to form a second photoresist layer, wherein the second photoresist layer has a fourth photoresist pattern and a fifth photoresist pattern which are sequentially increased in thickness;
Step S10, performing a first etching process using the second photoresist layer as a shielding layer to remove the second transparent conductive layer and the gate metal layer which are not covered by the second photoresist layer, wherein corresponding to an underside of the fourth photoresist pattern, a gate electrode and a metal common electrode line separated from the gate electrode which are corresponding to an upside of the amorphous silicon active layer are obtained; corresponding to an underside of the fifth photoresist pattern, a conductive connection block and a transparent common electrode line separated from the conductive connection block are obtained from the second transparent conductive layer; wherein the conductive connection block is contacted with the drain electrode and the pixel electrode respectively through the first via and the second via in order to electrically conduct the drain electrode and the pixel electrode;
Step S11, performing a first ashing treatment to the second photoresist layer, thinning the fifth photoresist pattern and removing the fourth photoresist pattern; and
Step S12, performing a second etching process using the second photoresist layer as a shielding layer to remove the gate metal layer corresponding to an upside of the conductive connection block and the transparent common electrode line, and peeling off a remaining portion of the second photoresist layer.

2. The manufacturing method for amorphous silicon TFT substrate according to claim 1, wherein in the step S2, the first mask process is performed by a Gray Tone Mask.

3. The manufacturing method for amorphous silicon TFT substrate according to claim 1, wherein in the step S9, the third mask process is performed by a Gray Tone Mask or a Half Tone Mask.

4. The manufacturing method for amorphous silicon TFT substrate according to claim 2, wherein in the step S2, the coated photoresist material is a positive photoresist material, and in the first mask process, the photoresist material is divided into four portions exposed under four exposure degrees that is gradually reduced from a full exposure degree to a non-exposure degree, the four portions that the exposure degrees are gradually decreased are respectively removed after developing in order to form the first photoresist pattern, the second photoresist pattern and the third photoresist pattern.

5. The manufacturing method for amorphous silicon TFT substrate according to claim 3, wherein in the step S9, the coated photoresist material is a positive photoresist material, and in the third mask process, the photoresist material is divided into three portions exposed under three exposure degrees that are from a full exposure degree to a non-exposure degree. The three portions exposed under the three exposure degrees are respectively removed after being developed in order to formed a fourth photoresist pattern and a fifth photoresist pattern.

6. The manufacturing method for amorphous silicon TFT substrate according to claim 1, wherein a material of each of the first transparent conductive layer and the second transparent conductive layer is indium tin oxide (ITO).

7. The manufacturing method for amorphous silicon TFT substrate according to claim 1, wherein in the step S1, the amorphous silicon layer, the N-type doped amorphous silicon layer, and the first transparent conductive layer are formed by a chemical vapor deposition (CVD), the source drain metal layer is formed by a sputter method.

8. The manufacturing method for amorphous silicon TFT substrate according to claim 1, wherein in the step S8, the passivation layer is formed by a chemical vapor deposition.

9. The manufacturing method for amorphous silicon TFT substrate according to claim 1, wherein in the step S9, the second transparent conductive layer is deposited by a chemical vapor deposition, and the gate metal layer is formed by a sputter method.

10. The manufacturing method for amorphous silicon TFT substrate according to claim 1, wherein in the step S1, the N-type doped amorphous silicon layer 30 is formed by adding phosphine during the deposition process.
